(19) United States
(12) Patent Application Publication
(10) Pub. No.: US 2012/0322171 A1
(43) Pub. Date: Dec. 20, 2012

(54) Apparatus and Method for Making an Absorbing layer of a Solar Cell

(75) Inventors: Wen-Chueh Pan, Taoyuan County (TW); Feng-Yu Tsai, Taoyuan County (TW); Hung-Chuan Hsu, Taoyuan County (TW); Hsiu-Jung Yeh, Taoyuan County (TW); Zan-Yu Chen, Taoyuan County (TW)

(73) Assignee: Chung-Shan Institute of Science and Technology, Armaments, Bureau, Ministry of National Defense, Taoyuan County (TW)

(21) Appl. No.: 13/453,343

(22) Filed: Apr. 23, 2012

(30) Foreign Application Priority Data
Jun. 17, 2011 (TW) 100121121

(51) Int. Cl. H01L 21/66; B05C 11/00

(52) U.S. Cl. 438/14; 118/712; 257/E21.521

(57) ABSTRACT

An apparatus for making an absorbing layer of a compound solar cell includes a transportation unit, a coating unit, a heat treatment unit, a measurement unit and a control unit. The transportation unit transports a substrate-based laminate. The coating unit provides coating liquid on the substrate-based laminate. The heat treatment unit treats the coated substrate-based laminate with heat to form a film. The measurement unit measures the film and provides correction parameters to the coating unit. The control unit controls the transportation unit, the coating unit, the heat treatment unit and the measurement unit.

### BACKGROUND OF INVENTION

1. Field of Invention

The present invention relates to an apparatus and method for making an absorbing layer of a solar cell and, more particularly, to a method for making an absorbing layer of a thin-film solar cell.

2. Related Prior Art

As industrialization advances, the consumption of petroleum grows. Hence, deposits of petroleum decrease, and the concentration of carbon dioxide in the atmosphere increases. The reduction of the deposits of petroleum causes the rising of the prices of petroleum which eventually causes economic recession and social panic. The increasing of the concentration of carbon dioxide in the atmosphere entails the global warning. Renewable energy seems a promising approach to the development of the industry and the protection of the environment. Solar cells provide renewable energy.

A solar cell transforms light to electricity and may be called “photovoltaic apparatus.” The solar cell includes an absorbing layer that includes signal crystal silicon, poly crystal, amorphous silicon, a III-V family compound such as GaAs, InP and InGaP or a II-VI compound such as CdTe and CuInSe₂.

In practice, all light is not absorbed and transformed to electricity by the solar cell. Light in about half of the spectrum does not contribute to the generation of the electricity at all for possessing little energy. About 50% of light in the second half spectrum is dissipated as heat. About 50% of the light in the second half spectrum is the transformed to electricity. Hence, the optimal efficiency of the solar cell is about 25%. In a laboratory, it is possible to make a solar cell with an efficiency of almost 25%. The production of such a solar cell is however complicated and expensive. Massive production of such solar cells is hence difficult if not impossible.

A thin-film solar cell includes films of different materials provided on a substrate. These materials may be compound semiconductors or silicon. The substrate may be made of glass, metal or plastics. For example, a CIGS solar cell may be made by vapor deposition, sputtering or inexpensive printing or ink jetting. The films may be made in vacuum or not. The making of the films in vacuum may be called “physical deposition.” The physical deposition may be selenization or co-evaporation. The making of the films not in vacuum may be called “chemical deposition.”

Companies like Shell Solar and Showa Shell use selenization processes. A selenization process may be called “two-stage process.” In a selenizaiton process, a precursor is quenched at high temperature in a certain environment. In early days, the precursor is selenized in H₂Se or vulcanized in H₂S after sputtering. Currently, a selenium layer is provided on the precursor by vapor deposition before they are heated for selenization. Compared with the co-evaporation, the selenizaiton does not effectively control the energy gaps between the materials used therein. However, the materials used in the selenization are not toxic, and the solar cells made by the selenization exhibit efficiencies higher than 14% (30 cm×30 cm). Hence, the selenization possesses values.

In the co-evaporation, the compositions of the films are well controlled. There have been three generations of co-evaporation, i.e., one-stage co-evaporation, two-stage co-evaporation and three-stage co-evaporation.

Currently, the three-stage co-evaporation was developed by the NREL. The CIGS solar cells made by the three-stage co-evaporation exhibit the highest efficiencies. At first, in low temperature, In:Ga (0.7:0.3) and Se are deposited to provide a smooth indium-gallium selenide base ({In,Ga}ₓSe_{y}). Then, at high temperature, the base is co-evaporated by Cu and Se so that it becomes Cu-rich. At 500° C. to 600° C., there are produced large and dense grains of Cu₂₋ₓSe. Finally, the concentration of the cupper is corrected by subsequent deposition of selenium, indium and gallium.

The physical deposition itself is inexpensive. However, equipment required by the physical deposition is expensive. Moreover, the equipment required by the physical deposition is bulky for having to provide high vacuum during the deposition. Hence, the costs of the solar cells processed in vacuum are high. In particular, the three-stage co-evaporation requires bulky equipment to make small solar cells, not to mention large solar cells.

In the chemical deposition, only inexpensive equipment is required, and the production of the solar cells is fast. Without any equipment for providing vacuum, a precursor and additives must be used to avoid contamination. The chemical deposition processes are classified in two groups. In the first group, the precursor is deposited on the substrate to directly form a CIGS compound. The first group includes spray pyrolysis and electrodeposition. In the second group, the precursor is deposited on the substrate before it is selenized. The second group includes paste coating and electrodeposition of mental layers. In these chemical deposition processes, the qualities of the products are not satisfactory although the films are made in constant compositions. Defects include poor purities of the phases of the materials and failed and inadequate crystallization caused by low temperature (<400° C.).

The chemical deposition reduces the costs for two reasons. At first, there is no need to provide vacuum. Secondly, the yields are high to reduce the unit costs. In conventional chemical deposition, the absorbing layer of a solar cell is made with thickness of several micrometers in a single round of coating, drying and heat treatment. There could be cracks in the absorbing layer or the thickness of the absorbing layer could be uneven.

The present invention is therefore intended to obviate or at least alleviate the problems encountered in prior art.

### SUMMARY OF INVENTION

It is the primary objective of the present invention to provide an inexpensive absorbing layer of a compound solar cell.

To achieve the foregoing objective, there is provided an apparatus for making an absorbing layer of a compound solar cell. The apparatus includes a transportation unit, a coating unit, a heat treatment unit, a measurement unit and a control unit. The transportation unit transports a substrate-based laminate. The coating unit provides coating liquid on the substrate-based laminate. The heat treatment unit treats the coated substrate-based laminate with heat to form a film. The measurement unit measures the film and provides correction parameters to the coating unit. The control unit controls the transportation unit, the coating unit, the heat treatment unit and the measurement unit.

In another aspect, there is provided a method for making an absorbing layer of a compound solar cell. The method includes the steps of providing a substrate-based laminate, providing coating liquid to form an absorbing material coating on the substrate-based laminate, treating the absorbing material coating with heat to provide an absorbing layer, and measuring the absorbing layer and providing correction parameters for another round of the foregoing steps. The steps are repeated for at least once to provide two absorbing layers with sub-micrometer thickness.

Other objectives, advantages and features of the present invention will be apparent from the following description referring to the attached drawings.

### BRIEF DESCRIPTION OF DRAWINGS

The present invention will be described via detailed illustration of several embodiments referring to the drawings wherein:

FIG. 1 is a block diagram of an apparatus for making an absorbing layer of a thin-film solar cell according to the first embodiment of the present invention;

FIG. 2 shows the making of an absorbing layer of a thin-film solar cell according to the first embodiment of the present invention;

FIG. 3 shows the making of another absorbing layer of a thin-film solar cell according to the first embodiment of the present invention;

FIG. 4 is a flow chart of a method for making an absorbing layer of a thin-film solar cell according to the second embodiment of the present invention.

### DETAILED DESCRIPTION OF EMBODIMENTS

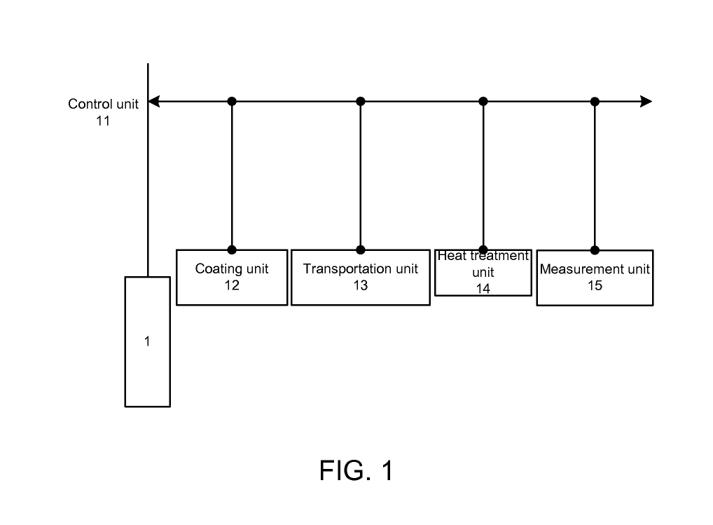

Referring to FIG. 1, shown is an apparatus 1 for making an absorbing layer of a compound solar cell according to a first embodiment of the present invention. The apparatus 1 includes a control unit 11, a coating unit 12, a transportation unit 13, a heat treatment unit 14 and a measurement unit 15. The control unit 11 controls the coating unit 12, the transportation unit 13, the heat treatment unit 14 and the measurement unit 15. The coating unit 12 provides coating liquid on a substrate-based laminate 2. The transportation unit 13 transports the coated substrate-based laminate 2. The heat treatment unit 14 treats the coated substrate-based laminate 2 with heat. The measurement unit 15 senses the heat-treated coating and sends correction parameters to the coating unit 12.

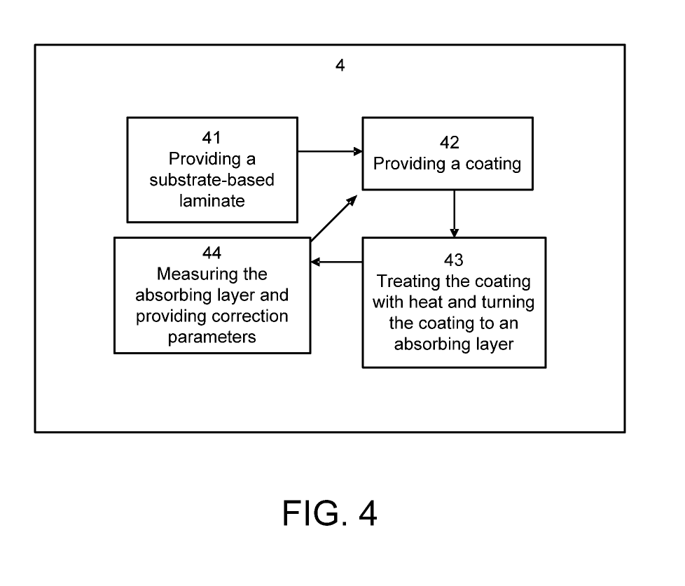

Referring to FIG. 4, there is shown a process for making an absorbing layer of a compound solar cell according to a second embodiment of the present invention. At first, a substrate-based laminate is provided. Secondly, a coating is provided on the substrate-based laminate to provide an absorbing material coating. Thirdly, the absorbing material layer is treated with heat to provide an absorbing layer. Fourthly, the thickness of the absorbing layer is measured, and results of the measurement are used to correct the coating. The steps are repeated at least once to provide two absorbing layers.

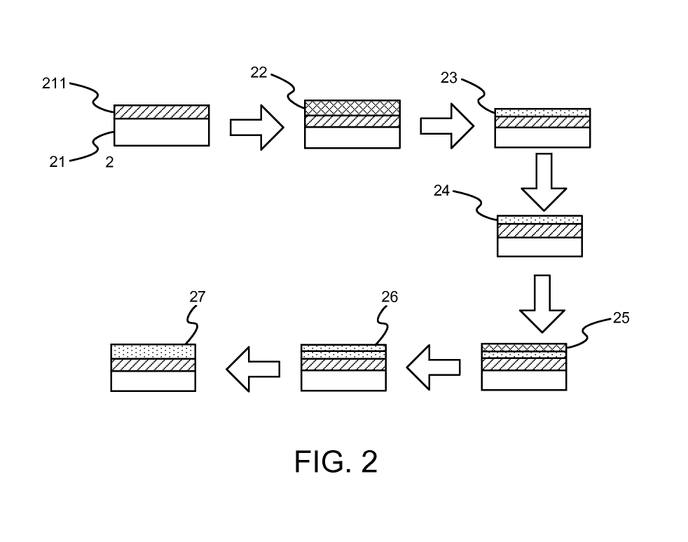

Referring to FIG. 2, a first absorbing layer of a solar cell is made in the apparatus 1 shown in FIG. 1 according to the process shown in FIG. 4. At first, there is provided a substrate-based laminate 2. The substrate-based laminate 2 includes a substrate 21 and a back electrode layer 211.

Then, the coating unit 12 provides coating liquid to form a first absorbing material coating 22 on the back electrode layer 211. The coating liquid includes nanometer grains of the material(s) for making the absorbing layer and appropriate dispersant. The thickness of the first absorbing material coating 22 is sub-micrometer.

Then, the first absorbing material coating 22 is dried to remove an excessive portion of the coating liquid. Thus, there is formed a first absorbing material layer 23. The thickness of the first absorbing material layer 23 is sub-micrometer.

Then, the heat treatment unit 14 rapidly treats the first absorbing material layer 23 with heat. Thus, there is formed a first absorbing layer 24. The thickness of the first absorbing layer 24 is sub-micrometer.

Then, the coating unit 12 provides more coating liquid to form a second absorbing material coating 25 on the first absorbing layer 24. The thickness of the second absorbing material coating 25 is sub-micrometer.

Then, the second absorbing material coating 25 is dried to remove an excessive portion of the coating liquid to form a second absorbing material layer 26. The thickness of the second absorbing material layer 26 is sub-micrometer.

Then, the heat treatment unit 14 treats the second absorbing material layer 26 with heat to join the second absorbing material layer 26 to the first absorbing layer 24. Thus, there is formed a second absorbing layer 27 on the first absorbing layer 24. The thickness of the second absorbing layer 27 is sub-micrometer.

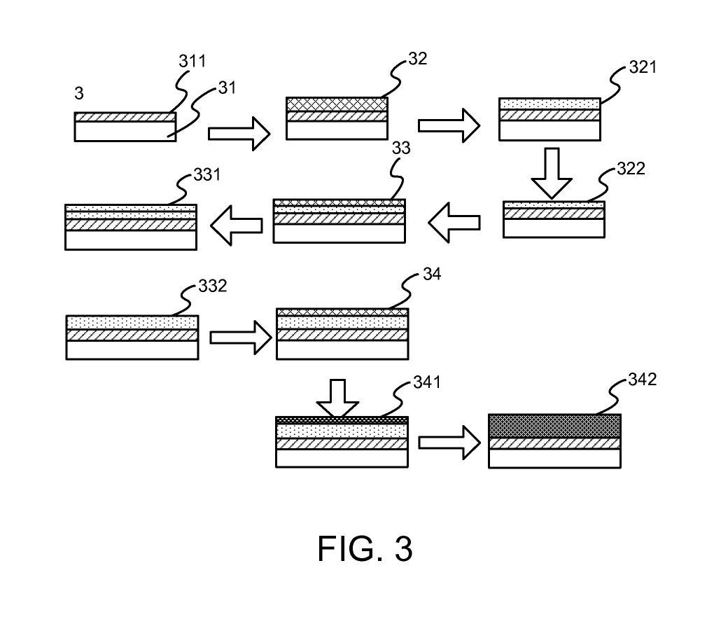

Referring to FIG. 3, a second absorbing layer of a CIGS solar cell is made in the apparatus 1 shown in FIG. 1 according to the process shown in FIG. 4. At first, there is provided a CIGS substrate-based laminate 3. The CIGS substrate-based laminate 3 includes a CIGS substrate 31 and a Mo back electrode layer 311.

Then, the coating unit 12 provides coating liquid to form a first Cu-rich CIGS material coating 32 on the Mo back electrode layer 311. The coating liquid includes nanometer grains of the material(s) for making the CIGS absorbing layer and appropriate dispersant. The thickness of the first Cu-rich CIGS material coating 32 is sub-micrometer.

Then, the first Cu-rich CIGS material coating 32 is dried to remove an excessive portion of the coating liquid. Thus, there is formed a first Cu-rich CIGS absorbing material layer 321. The thickness of the first Cu-rich CIGS absorbing material layer 321 is sub-micrometer.

Then, the heat treatment unit 14 treats the first Cu-rich CIGS absorbing material layer 321 to form a first Cu-rich CIGS absorbing layer 322. The thickness of the first Cu-rich CIGS absorbing layer 322 is sub-micrometer.

Then, the coating unit 12 provides more coating liquid to form a second Cu-rich CIGS material coating 33 on the first Cu-rich CIGS absorbing layer 322. The thickness of the second Cu-rich CIGS material coating 33 is sub-micrometer.

Then, the second Cu-rich CIGS material coating 33 is dried to remove an excessive portion of the coating liquid. Thus, there is formed a second Cu-rich CIGS absorbing material layer 331 on the first Cu-rich CIGS absorbing layer 322. The thickness of the second Cu-rich CIGS absorbing material layer 331 is sub-micrometer.

Then, the heat treatment unit 14 treats the second Cu-rich CIGS absorbing material layer 331 with heat to join the second Cu-rich CIGS absorbing material layer 331 to the first Cu-rich CIGS absorbing layer 322. Thus, there is formed a second Cu-rich CIGS absorbing layer 332 on the first Cu-rich CIGS absorbing layer 322. The thickness of the second Cu-rich CIGS absorbing layer 332 is sub-micrometer.

Then, the coating unit 12 provides more coating liquid to form a third Cu-poor CIGS material coating 34 on the second Cu-rich CIGS absorbing layer 332. The thickness of the third Cu-poor CIGS material coating 34 is sub-micrometer.

Then, the third Cu-poor CIGS material coating 34 is dried to remove an excessive portion of the coating liquid. Thus, there is formed a third Cu-poor CIGS absorbing material layer 341. The thickness of the third Cu-poor CIGS absorbing material layer 341 is sub-micrometer.

The heat treatment unit 14 treats the third Cu-poor CIGS absorbing material layer 341 with heat to join the third Cu-poor CIGS absorbing material layer 341 to the second Cu-rich CIGS absorbing layer 332. Thus, there is formed a third CIGS absorbing layer 342 on the second Cu-rich CIGS absorbing layer 332. The thickness of the third CIGS absorbing layer 342 is sub-micrometer.

As described in relation to FIG. 2, two absorbing layers 24 and 27 are formed. As described in relation to FIG. 3, three absorbing layers 322, 332 and 342 are formed. The number of the absorbing layers is determined at a manufacturer's discretion and not limited in the present invention.

The present invention has been described via the detailed illustration of the embodiments. Those skilled in the art can derive variations from the embodiments without departing from the scope of the present invention. Therefore, the embodiments shall not limit the scope of the present invention defined in the claims.

1. An apparatus for making an absorbing layer of a compound solar cell, the apparatus including:
a transportation unit 13 for transporting a substrate-based laminate 2;
a coating unit 12 for providing coating liquid on the substrate-based laminate 2;
a heat treatment unit 14 for treating the coated substrate-based laminate 2 with heat to form a film;
a measurement unit 15 for measuring the film and providing correction parameters to the coating unit; and
a control unit 11 for controlling the transportation unit 13, the coating unit 12, the heat treatment unit 14 and the measurement unit 15.

2. The apparatus for making an absorbing layer of a compound solar cell according to claim 1, wherein the substrate-based laminate includes a substrate 21 and a back electrode layer 211.

3. The apparatus for making an absorbing layer of a compound solar cell according to claim 2, wherein the substrate 21 is made of metal.

4. The apparatus for making an absorbing layer of a compound solar cell according to claim 2, wherein the substrate 21 is made of polymer.

5. The apparatus for making an absorbing layer of a compound solar cell according to claim 2, wherein the substrate 21 is made of glass.

6. The apparatus for making an absorbing layer of a compound solar cell according to claim 2, wherein the heat treatment unit 14 uses a rapid thermal process.

7. A method for making an absorbing layer of a compound solar cell including the steps of:
providing a substrate-based laminate;
providing coating liquid to form an absorbing material coating on the substrate-based laminate;
treating the absorbing material coating with heat to provide an absorbing layer; and
measuring the absorbing layer and providing correction parameters for another round of the foregoing steps, wherein the steps are repeated for at least once to provide two absorbing layers with sub-micrometer thickness.

8. The method for making an absorbing layer of a compound solar cell according to claim 7, wherein the substrate-based laminate includes a substrate 21 and a back electrode layer 211.

9. The method for making an absorbing layer of a compound solar cell according to claim 8, wherein the substrate 21 is made of metal.

10. The method for making an absorbing layer of a compound solar cell according to claim 8, wherein the substrate 21 is made of polymer.

11. The method for making an absorbing layer of a compound solar cell according to claim 8, wherein the substrate 21 is made of glass.

12. The method for making an absorbing layer of a compound solar cell according to claim 8, wherein the back electrode layer 211 is made of a material that exhibits ohm contact with the absorbing layer.

13. The method for making an absorbing layer of a compound solar cell according to claim 7, wherein the coating liquid includes nanometer grains of at least one material for making the absorbing layer and appropriate dispersant.

14. The method for making an absorbing layer of a compound solar cell according to claim 7, wherein the heat treatment is a rapid thermal process.
